(19) United States
(12) Patent Application Publication
(10) Pub. No.: US 2015/0189784 A1
(43) Pub. Date: Jul. 2, 2015

(54) Electric Circuit Apparatus and Method for Producing Electric Circuit Apparatus

(71) Applicant: Hitachi, Ltd., Chiyoda-ku, Tokyo (JP)

(72) Inventors: Satoshi Hirano, Tokyo (JP); Akihiro Namba, Tokyo (JP); Makoto Ogata, Tokyo (JP); Takeshi Tokuyama, Tokyo (JP); Kinya Nakatsu, Tokyo (JP)

(21) Appl. No.: 14/418,724

(22) PCT Filed: Jul. 22, 2013
(86) PCT No.: PCT/JP2013/069727

§ 371 Date: Jan. 30, 2015

(30) Foreign Application Priority Data
Aug. 29, 2012 (JP) 2012-188543

(51) Int. Cl. H05K 7/02; H02M 7/537

(52) U.S. Cl. CPC H05K 7/02; H02M 7/537

(57) ABSTRACT

An electric circuit apparatus includes a power module (300) including a DC positive electrode branch terminal (315D) and a DC negative electrode branch terminal (319D), and a power board (700) which is configured to transfer a direct current and which includes a power board P bus bar and a power board N bus bar sealed by a resin member, which has an insulation property, in such a manner that a P terminal (701) and an N terminal (702) are exposed. The DC positive electrode branch terminal (315D) and the P terminal (701) are held by a flexion member (904) and are connected to each other via a metal joining member having a melting point lower than those of the both terminals. The DC negative electrode branch terminal (319D) and the N terminal (702) are connected to each other in a similar manner. Thus, a thermal influence on the resin member can be reduced and connection durability can be improved.

### TECHNICAL FIELD

The present invention relates to an electronic circuit apparatus, which is configured to transfer a direct current to an electronic circuit component through a DC bus bar, such as a power conversion apparatus to convert a direct current into an alternating current and also relates to a method for producing the electronic circuit apparatus.

### BACKGROUND ART

Recently, while a power conversion apparatus capable of outputting a large current has been desired, downsizing of the power conversion apparatus has been also desired. When the power conversion apparatus tries to output a large current, heat generated in a power semiconductor element embedded in a power module becomes large. In a case where cooling capacity of the power module or that of the power conversion apparatus is not improved, a heatproof temperature of the power semiconductor element is reached and breakage may be caused. Thus, a both-surface cooling type power module to improve cooling efficiency by cooling both surfaces of the power semiconductor element has been developed (see, for example, PTL 1).

The both-surface cooling type power module includes a configuration in which both main surfaces of the power semiconductor element are sandwiched by a lead frame which is a tabular conductor. Then, a surface of the lead frame which surface does not face a main surface of the power semiconductor element is thermally connected to a cooling medium, and thus, cooling of the power module is performed.

In the invention described in PTL 1, both main surfaces of a power semiconductor element which configures upper and lower arms in an inverter circuit are sandwiched by a lead frame which is a tabular conductor, and thus, a series circuit of upper and lower arms is configured, the upper and lower arms of the inverter circuit being connected in series in the circuit. Then, a DC positive electrode wiring line and a DC negative electrode wiring line extended from each conductor are arranged oppositely in parallel and a resin sealing member is arranged therebetween. Thus, it is made possible to secure an insulation property, to reduce a wiring inductance, and to perform downsizing. The DC positive electrode wiring line and the DC negative electrode wiring line are respectively connected to a positive electrode bus bar and a negative electrode bus bar. For the joining, fusion joining, which is to perform joining by melting a connection member, such as what is described in PTL 2 is used.

### CITATION LIST

### Patent Literature

### PTL 1: JP 2011-77464 A

### PTL 2: JP 3903994 B1

### SUMMARY OF INVENTION

### Technical Problem

Incidentally, in making a power conversion apparatus output a large current, it has been difficult to ensure compatibility with reducing a loss in a power semiconductor element. In order to realize the compatibility, it is necessary to perform high-speed switching of a power semiconductor element with a low loss. Then, in order to perform the high-speed switching, it is necessary to control a surge voltage generated due to a wiring inductance which exists in a wiring conductor included in an inverter circuit. In order to reduce the wiring inductance, a configuration to proximately arrange a transient current which flows in an opposite direction is effective. The configuration is known widely as a laminate structure of a DC positive electrode and a DC negative electrode.

However, as described above, in a case of fusion joining to perform joining by melting a connection member, such as a case of performing welding by TIG welding, a radiant heat is high and there is a thermal influence on a member (specifically, insulating member such as resin member) around the connection member. Also, along with downsizing of an apparatus, a space between a bus bar and the other components becomes small and a thermal influence on a member (specifically, resin member) around a joint part becomes a problem.

### Solution to Problem

The invention of claim 1 provides an electric circuit apparatus including: an electric circuit component including a DC terminal; a power board configured to transfer a direct current, the power board including a positive electrode plate and a negative electrode plate sealed by a resin sealing material, which has an insulation property, in such a manner that a connection terminal part is exposed; and a flexion member which is connected via a metal joining member having a melting point lower than those of the DC terminal and the connection terminal part, and which holds the DC terminal and the connection terminal part.

The invention of claim 7 provides a method for producing an electric circuit apparatus including an electric circuit component which includes a DC terminal, and a power board which is configured to transfer a direct current and which includes a positive electrode plate and a negative electrode plate sealed by a resin sealing material, which has an insulation property, in such a manner that a connection terminal part is exposed, the method including: a first step in which a leading end part of the connection terminal part and a leading end part of the DC terminal are held integrally by a flexion member in a state in which a metal joining member having a melting point lower than those of the connection terminal part and the DC terminal is arranged therebetween; and a second step in which the connection part and the terminal are connected to each other by melting the metal joining member and solidifying the metal joining member again.

### Advantageous Effects of Invention

According to the present invention, it is possible to secure durability of a connection part between a DC terminal and a connection terminal part by using a flexion member while reducing a thermal influence on a surrounding during connection of the DC terminal and the connection terminal part.

### BRIEF DESCRIPTION OF DRAWINGS

FIG. 1 is a view illustrating a control block of a hybrid automobile.

FIG. 2 is a view illustrating an electric circuit configuration of an inverter apparatus 140.

FIG. 3 is an exploded perspective view of a power conversion apparatus 143.

FIG. 4 is a perspective view of an inverter main circuit unit 250.

FIG. 5 (a) and FIG. 5 (b) are views for describing a power module 300.

FIG. 6 is a view illustrating a circuit diagram of an electronic component sealed by a primary sealing body 302.

FIG. 7 is a perspective view illustrating the primary sealing body 302 from which a sealing resin is removed.

FIG. 8 is an exploded perspective view of the primary sealing body 302.

[FIG. 9 (a) and FIG. 9 (b)] FIG. 9 (a) and FIG. 9 (b) are views for describing mounting of the primary sealing body 302 to a cooler 304.

FIG. 10 is an exploded perspective view in which a channel cover 308A is detached from the cooler 304.

FIG. 11 is an exploded perspective view illustrating an inner structure of a capacitor module 500.

FIG. 12 is a view in which a part of the inverter main circuit unit 250 is enlarged and illustrated.

[FIG. 13 (a) and FIG. 13 (b)] FIG. 13 (a) and FIG. 13 (b) are views illustrating a structure of a power board 700.

[FIG. 14 (a) to FIG. 14 (c)] FIG. 14 (a) to FIG. 14 (c) are views for describing a procedure of connecting a P terminal 701 and a DC positive electrode branch terminal 315D.

[FIG. 15 (a) and FIG. 15 (b)] FIG. 15 (a) and FIG. 15 (b) are views illustrating an example of modification of a metal joining member.

[FIG. 16 (a) to FIG. 16 (c)] FIG. 16 (a) to FIG. 16 (c) are views illustrating an example of modification of a flexion member 904.

[FIG. 17 (a) and FIG. 17 (b)] FIG. 17 (a) and FIG. 17 (b) are views for describing a PN wiring insulation part 601.

[FIG. 18 (a) to FIG. 18 (c)] FIG. 18 (a) to FIG. 18 (c) are views for describing a connection structure of a capacitor cell 503 and the power board 700.

FIG. 19 is a view illustrating a path of a recovery current during a switching operation.

FIG. 20 is a circuit diagram illustrating the recovery current path.

### DESCRIPTION OF EMBODIMENTS

In the following, an embodiment of the present invention will be described with reference to the drawings. The present invention relates to an electronic circuit apparatus, which is configured to transmit a direct current to an electronic circuit component through a DC bus bar, such as a power conversion apparatus to convert a direct current into an alternating current. Specifically, the present invention is suitable for an in-vehicle power conversion apparatus in which a mounting environment, an operation environment, or the like is severe. In the following, a case where application to a power conversion apparatus of a hybrid automobile is performed will be described as an example. However, application is not limited to the hybrid automobile and application to a plain electric automobile is also possible.

An inverter apparatus for driving a vehicle controls driving of a motor for driving a vehicle by converting DC power, which is supplied by an in-vehicle battery or an in-vehicle power generation apparatus included in an in-vehicle power supply, into predetermined AC power and by supplying the acquired AC power to the motor for driving a vehicle. Also, the motor for driving a vehicle includes a function as a power generator. Thus, the inverter apparatus for driving a vehicle also includes a function to convert AC power generated by the motor for driving a vehicle into DC power according to a driving mode.

Note that a configuration of the present embodiment is optimal as a power conversion apparatus for driving a vehicle such as an automobile or a truck. However, the configuration of the present embodiment can also be applied to a different power conversion apparatus such as a power conversion apparatus of a train, a ship, an airplane, or the like, an industrial power conversion apparatus used as a control apparatus of a motor to drive equipment in a factory, or a household power conversion apparatus used for a household solar power generation system or a control apparatus of a motor to drive a household electrical appliance.

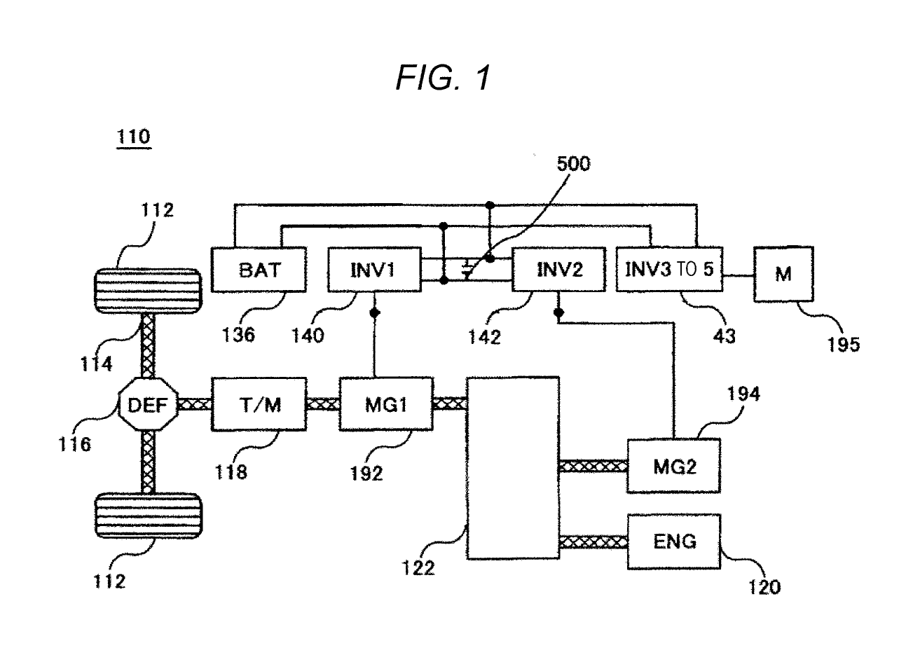

FIG. 1 is a view illustrating a control block of a hybrid automobile. In FIG. 1, a hybrid electric automobile (hereinafter, referred to as “HEV”) 110 is one electric vehicle and includes two systems for driving a vehicle. One is an engine system a power source of which is an engine 120 which is an internal-combustion engine. The engine system is mainly used as a drive source of the HEV. The other is an in-vehicle electric machine system power sources of which are motor generators 192 and 194. The in-vehicle electric machine system is mainly used as a drive source of the HEV and a power generation source of the HEV. Each of the motor generators 192 and 194 is, for example, a synchronous machine or an induction machine and can be operated as a motor or a power generator according to an operation method. Thus, here, each of the motor generators 192 and 194 is referred to as a motor generator.

To a front part of a vehicle body, a front wheel axle 114 is supported rotatably. To both ends of the front wheel axle 114, a pair of front wheels 112 is provided. Although not illustrated, to a rear part of the vehicle body, a rear wheel axle is supported rotatably and a pair of rear wheels is provided to both ends of the rear wheel axle. In the HEV described in the present embodiment, a so-called front wheel drive system is employed but an opposite thereof, that is, a rear wheel drive system may be employed.

To a center part of the front wheel axle 114, a front wheel-side differential gear (hereinafter, referred to as “front wheel-side DEF”) 116 is provided. To an input side of the front wheel-side DEF 116, an output shaft of a transmission 118 is mechanically connected. To an input side of the transmission 118, an output side of the motor generator 192 is mechanically connected. To an input side of the motor generator 192, an output side of the engine 120 and an output side of the motor generator 194 is mechanically connected through a power transfer mechanism 122. Note that the motor generators 192 and 194 and the power transfer mechanism 122 are housed in an inner part of a housing of the transmission 118.

To inverter apparatuses 140 and 142, a battery 136 is electrically connected. Transmission/reception of power between the battery 136 and the inverter apparatuses 140 and 142 is possible.

In the present embodiment, the HEV 110 includes a first electric motor generator unit including the motor generator 192 and the inverter apparatus 140 and a second electric motor generator unit including the motor generator 194 and the inverter apparatus 142. These units are selectively used depending on an operation state. For example, in order to assist a drive torque of the vehicle in a case where a vehicle is driven by power from the engine 120, the second electric motor generator unit is actuated as a power generation unit and is made to generate power by the power from the engine 120. The first electric motor generator unit is actuated as an electric unit by the power acquired by the power generation. Also, in order to assist a speed of the vehicle in a similar case, the first electric motor generator unit is actuated as a power generation unit and is made to generate power by power from the engine 120. The second electric motor generator unit is actuated as an electric unit by the power acquired by the power generation.

Also, in the present embodiment, by actuating the first electric motor generator unit as an electric unit by power from the battery 136, a vehicle can be driven only by the power from the motor generator 192. Moreover, in the present embodiment, the first electric motor generator unit or the second electric motor generator unit is actuated as a power generation unit and is made to generate power by the power from the engine 120 or power from the wheels. Thus, it is possible to charge the battery 136.

Furthermore, the battery 136 is also used as a power supply to drive a motor for an auxiliary machine 195. As an auxiliary machine, for example, there is a motor to drive a compressor of an air conditioner or a motor to drive a hydraulic pump for control. DC power is supplied from the battery 136 to an inverter apparatus 43. The DC power is converted into AC power in the inverter apparatus 43 and is supplied to a motor 195. The inverter apparatus 43 includes a function similar to those of the inverter apparatuses 140 and 142 and controls an AC phase, frequency, or power supplied to the motor 195. For example, by supplying AC power of a leading phase to rotation of a rotor of the motor 195, the motor 195 generates a torque. On the other hand, by generating AC power of a lagging phase, the motor 195 functions as a power generator and the motor 195 is operated in a regenerative braking state. Such a control function of the inverter apparatus 43 is similar to a control function of each of the inverter apparatuses 140 and 142. Since a capacity of the motor 195 is smaller than a capacity of each of the motor generators 192 and 194, the maximum conversion power of the inverter apparatus 43 is smaller than those of the inverter apparatuses 140 and 142. However, a circuit configuration of the inverter apparatus 43 is basically identical to circuit configurations of the inverter apparatuses 140 and 142.

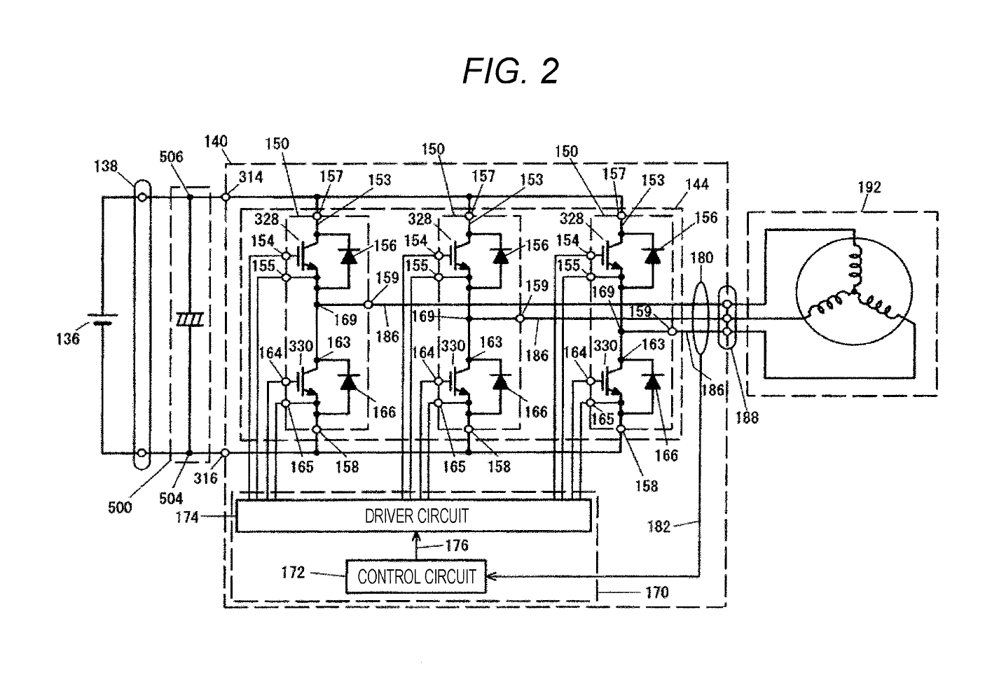

Next, with reference to FIG. 2, an electric circuit configuration of the inverter apparatus 140, the inverter apparatus 142, or the inverter apparatus 43 will be described. Note that in FIG. 2, the inverter apparatus 140 will be described as an example.

In an inverter circuit 144, three phases (U-phase, V-phase, and W-phase) of series circuit of upper and lower arms 150 are provided corresponding to phase winding wires of an armature winding wire of the motor generator 192. The series circuit of upper and lower arms 150 includes an IGBT 328 and a diode 156 which operate as an upper arm and an IGBT 330 and a diode 166 which operate as a lower arm. A middle point (intermediate electrode 169) of each series circuit of upper and lower arms 150 is connected to an AC power line (AC bus bar) 186 to the motor generator 192 through an AC terminal 159 and an AC connector 188.

A collector electrode 153 of the IGBT 328 of the upper arm is electrically connected to an electrode of a capacitor on a positive electrode side of a capacitor module 500 through a positive electrode terminal (P terminal) 167. An emitter electrode of the IGBT 330 of the lower arm is electrically connected to a capacitor electrode on a negative electrode side of the capacitor module 500 though a negative electrode terminal (N terminal) 168.

A control unit 170 includes a driver circuit 174 to perform driving control of the inverter circuit 144, and a control circuit 172 to supply a control signal to a driver circuit 174 through a signal line 176. The IGBT 328 or the IGBT 330 operates when receiving a drive signal output from the control unit 170 and converts the DC power supplied from the battery 136 into three-phase AC power. The converted power is supplied to the armature winding wire of the motor generator 192.

The IGBT 328 includes a collector electrode 153, an emitter electrode for a signal 151, and a gate electrode 154. The IGBT 330 includes a collector electrode 163, an emitter electrode for a signal 165, and a gate electrode 164. Also, to the IGBT 328, the diode 156 is connected in parallel electrically. To the IGBT 330, a diode 158 is connected in parallel electrically. As a power semiconductor element for switching, a metal-oxide semiconductor field-effect transistor (MOSFET) may be used. However, in such a case, the diode 156 and the diode 158 are not necessary.

A positive electrode-side capacitor terminal 506 and a negative electrode-side capacitor terminal 504 of the capacitor module 500 are electrically connected to the battery 136 through a DC connector 138. Note that the inverter apparatus 140 is connected to the positive electrode-side capacitor terminal 506 through a DC positive electrode terminal 314 and is connected to the negative electrode-side capacitor terminal 504 through a DC negative electrode terminal 316.

The control circuit 172 includes a microcomputer to perform calculation processing of switching timing of the IGBTs 328 and 330. Into the microcomputer, a target torque value requested to the motor generator 192, a current value supplied from the series circuit of upper and lower arms 150 to the armature winding wire of the motor generator 192, and a magnetic pole position of the rotor of the motor generator 192 are input as input information.

The target torque value is based on a command signal output from a host control apparatus (not illustrated). The current value is detected based on a detection signal output from a current sensor 180 through a signal line 182. The magnetic pole position is detected based on a detection signal output from a rotary magnetic pole sensor (not illustrated) provided in the motor generator 192. In the present embodiment, a case where a three-phase current value is detected will be described as an example. However, a two-phase current value may be detected.

The microcomputer inside the control circuit 172 calculates a current command value in d and q axes of the motor generator 192 based on the target torque value and calculates a voltage command value in the d and q axes based on a difference between the calculated current command value in the d and q axes and a detected current value in the d and q axes. Then, the microcomputer converts the calculated voltage command value in the d and q axes into a voltage command value in each of the U-phase, V-phase, and W-phase based on a detected magnetic pole position. Then, the microcomputer generates a pulsed modulation wave based on comparison between a basic wave (sine wave), which is based on the voltage command value in each of the U-phase, V-phase, and W-phase, and a carrier wave (triangular wave). The microcomputer outputs the generated modulation wave as a pulse-width modulation (PWM) signal to the driver circuit 174 through the signal line 176.

In a case of driving a lower arm, the driver circuit 174 outputs a drive signal, which is an amplified PWM signal, to a gate electrode of an IGBT 330 of a corresponding lower arm. Also, in a case of driving an upper arm, the driver circuit 174 shifts a level of reference potential of a PWM, signal to a level of reference potential of the upper arm and amplifies the PWM signal. Then, the driver circuit 174 outputs the PWM signal as a drive signal to a gate electrode of an IGBT 328 of a corresponding upper arm.

Also, the control unit 170 performs trouble detection (such as overcurrent, overvoltage, or overtemperature) and protects the series circuit of upper and lower arms 150. Thus, into the control unit 170, sensing information is input. For example, from the emitter electrode for a signal 151 and the emitter electrode for a signal 165 of each arm, information of a current which flows in the emitter electrode of each of the IGBTs 328 and 330 is input into a corresponding drive unit (IC). Accordingly, each drive unit (IC) performs detection of overcurrent. In a case where the overcurrent is detected, a switching operation of corresponding IGBTs 328 and 330 is stopped and the corresponding IGBTs 328 and 330 are protected from the overcurrent.

From a temperature sensor (not illustrated) provided in the series circuit of upper and lower arms 150, temperature information of the series circuit of upper and lower arms 150 is input into the microcomputer. Also, into the microcomputer, voltage information on a DC positive electrode side of the series circuit of upper and lower arms 150 is input. The microcomputer performs overtemperature detection and overvoltage detection based on these pieces of information. In a case where overtemperature or overvoltage is detected, a switching operation of all IGBTs 328 and 330 are stopped.

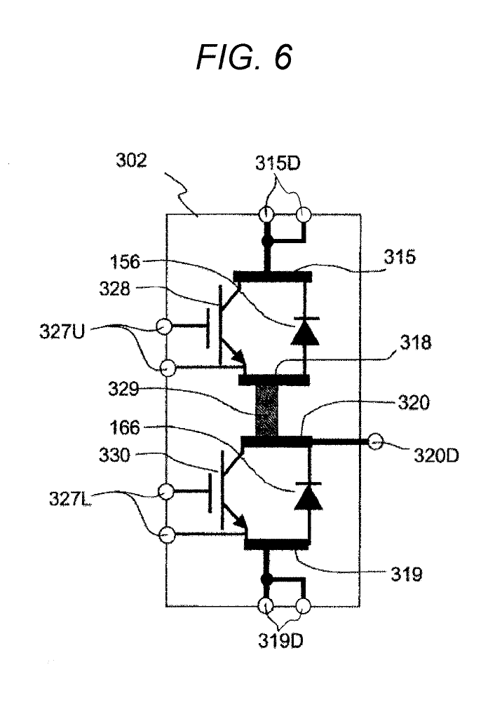

Note that the gate electrode 154 and an emitter electrode for a signal 155 in FIG. 2 correspond to a signal connection terminal for an upper arm 327U in FIG. 6 which will be described later. The gate electrode 164 and the emitter electrode 165 correspond to a signal connection terminal for a lower arm 327L in FIG. 6. Also, a positive electrode terminal 157 is identical to the DC positive electrode branch terminal 315D in FIG. 6. A negative electrode terminal 158 is identical to a DC negative electrode branch terminal 319D in FIG. 6. Also, the AC terminal 159 is identical to an AC terminal 320B in FIG. 6.

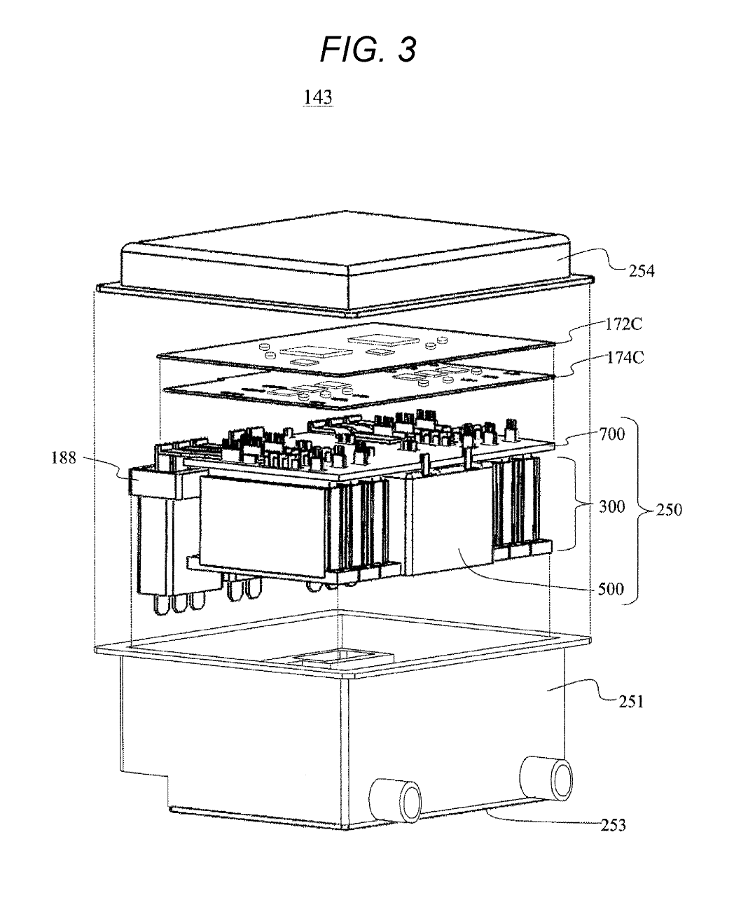

FIG. 3 is an exploded perspective view of the power conversion apparatus 143. The power conversion apparatus 143 configures a power conversion apparatus which includes two inverters. In the power conversion apparatus, the inverter apparatus 140 and the inverter apparatus 142 illustrated in FIG. 1 are housed in the same housing. The housing includes a channel housing 251, a channel cover 253, and a housing cover 254. In the housing, a power module 300 of each of the above-described inverter apparatuses 140 and 142, a capacitor module 500, a power board 700, a driver circuit board 174C, and a control circuit board 172C are housed. The power board 700, the driver circuit board 174C, and the control circuit board 172C are common to the inverter apparatuses 140 and 142.

In FIG. 3, the plurality of power modules 300, the power board 700 to transfer a direct current, and the capacitor module 500 are integrated and configure the inverter main circuit unit 250 which forms a main circuit unit of the inverter circuit.

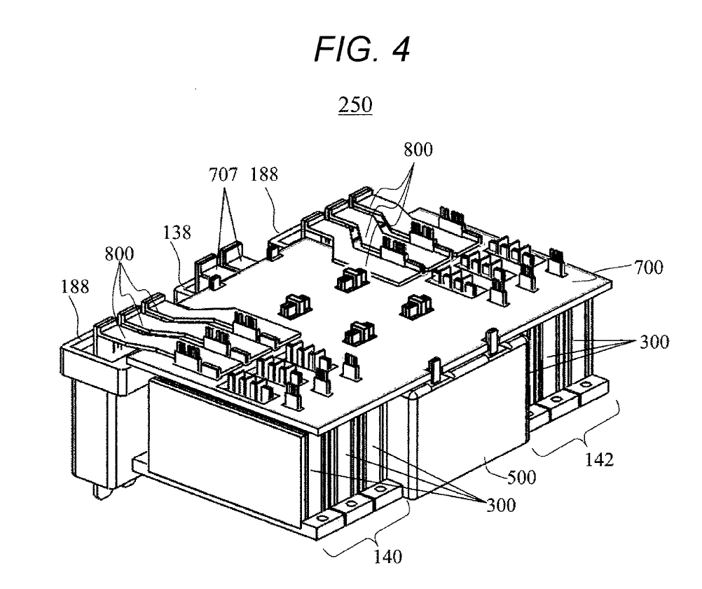

FIG. 4 is a perspective view of the inverter main circuit unit 250. Three power modules 300 of the inverter apparatus 140 is arranged on one side of the capacitor module 500 and three power modules 300 of the inverter apparatus 142 is arranged on the other side of the capacitor module 500, the power board 700 being arranged in such a manner as to cover an upper part of thereof. To the power board 700, openings are respectively formed at positions facing a DC terminal (DC positive electrode branch terminal 315D and DC negative electrode branch terminal 319D which will be described later) and an AC terminal of each power module 300 and a DC terminal of the capacitor module 500. Each terminal pierces through the opening and projects upward. An AC terminal of each power module 300 is connected to the AC connector 188 through an AC bus bar 800. A power board DC terminal 707 of the power board 700 is connected to the DC connector 138.

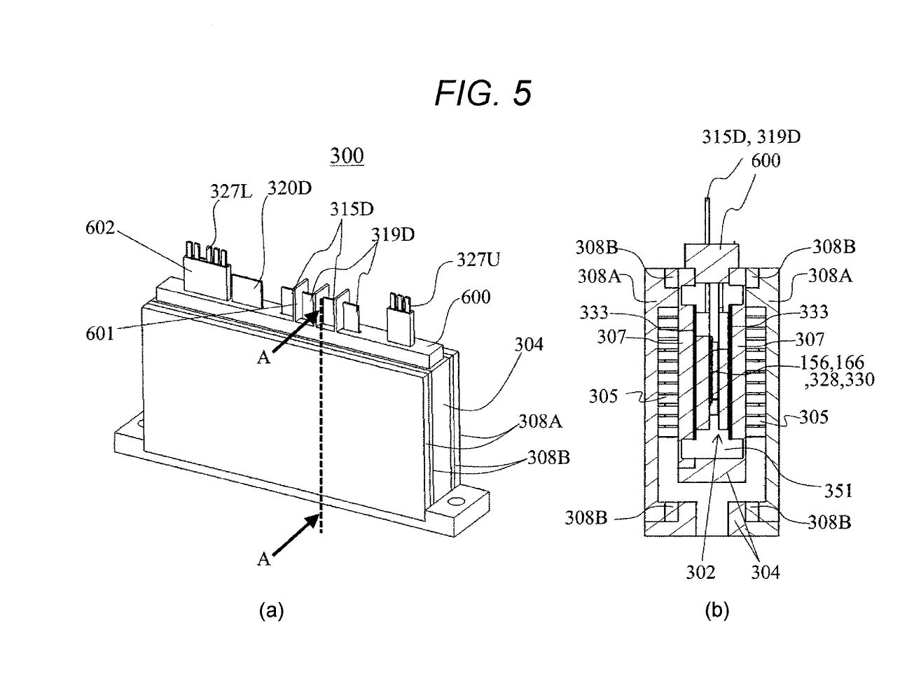

A structure of each power module 300 will be described. FIG. 5 (a) is a perspective view of the power module 300 and FIG. 5 (b) is an A-A sectional view thereof. To the power module 300, a power semiconductor element which configures one series circuit of upper and lower arms 150 in the inverter circuit 144 illustrated in FIG. 2 is provided. As illustrated in FIG. 5 (b), in the power module 300, a plurality of power semiconductor elements (IGBT 328 and 330 and diode 156 and 166) and the primary sealing body 302 in which a conductor plate is sealed are embedded in an inner part of the cooler 304. The power module 300 configures a both-surface cooling type power module.

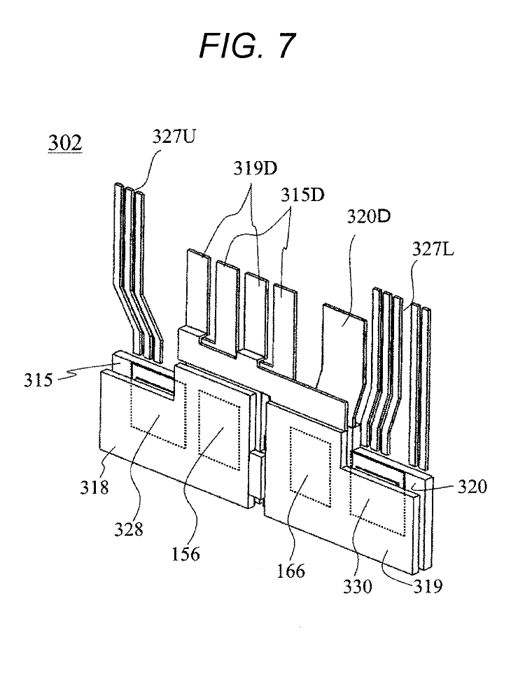

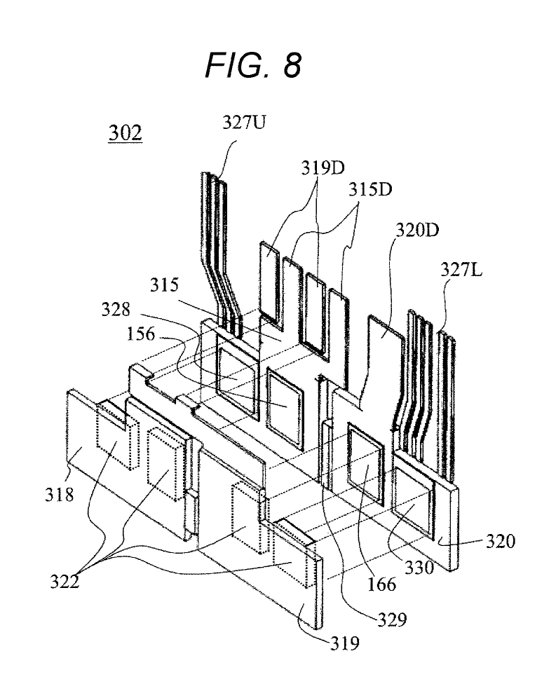

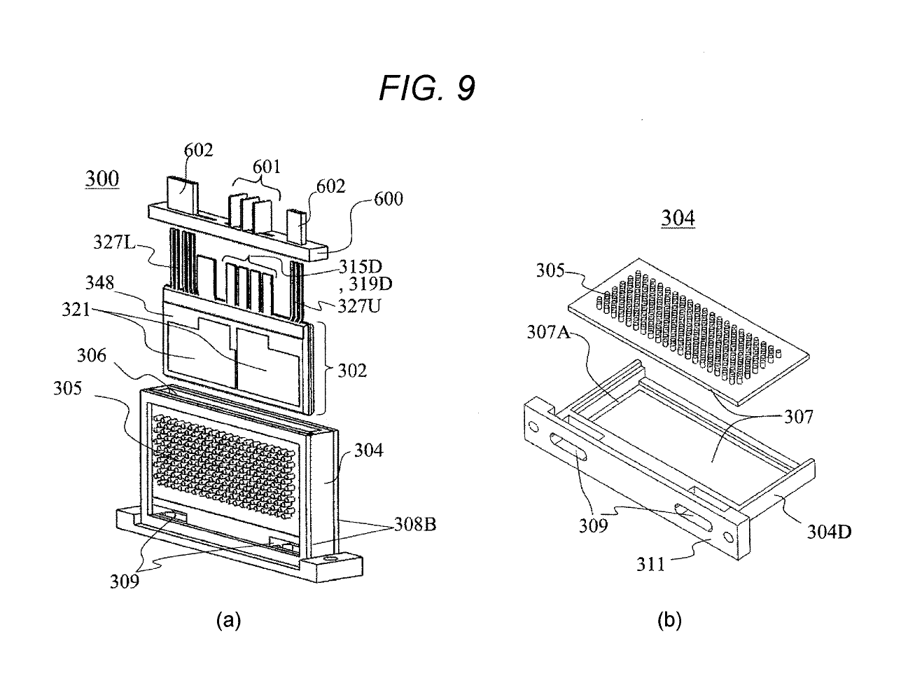

FIG. 6 is a circuit diagram of an electronic component sealed in the primary sealing body 302 of the power module 300. FIG. 7 is a perspective view illustrating the primary sealing body 302 from which a sealing resin is removed, and FIG. 8 is an exploded perspective view thereof. As illustrated in FIG. 6, the power module 300 includes a structure in which an upper arm and a lower arm of the inverter circuit are connected in series.

A collector electrode of the IGBT 328 and a cathode electrode of the diode 156 which configure the upper arm circuit are joined on a conductor plate 315 by a metal joining material. On the other and, the emitter electrode of the IGBT 328 and an anode electrode of the diode 156 are joined, by using a metal joining material, to an electrode joint part 322 formed on a conductor plate 318. A collector electrode of the IGBT 330 and a cathode electrode of the diode 166 which configure the lower arm circuit are joined on a conductor plate 320 by a metal joining material. On the other hand, the emitter electrode of the IGBT 330 and an anode electrode of the diode 166 are joined, by using a metal joining material, to the electrode joint part 322 formed on a conductor plate 319. Then, the conductor plate 318 of the upper arm circuit and the conductor plate 320 of the lower arm circuit are connected to each other through an intermediate electrode 329. A metal joining material is also used for joining of the intermediate electrode 329 and the conductor plates 318 and 320.

To the conductor plate 315, a plurality of DC positive electrode branch terminals 315D is provided. To the conductor plate 319, a plurality of DC negative electrode branch terminals 319D is provided. The plurality of DC positive electrode branch terminals 315D and DC negative electrode branch terminals 319D is arranged alternately. To the conductor plate 320, an AC connection terminal 320D is provided and arranged in parallel with the DC positive electrode branch terminals 315D and the DC negative electrode branch terminals 319D. In the IGBTs 328 and 330, signal electrodes are respectively formed on the same surfaces with the emitter electrode surfaces and are respectively connected to the signal connection terminal for an upper arm 327U and the signal connection terminal for a lower arm 327L by wire bonding (not illustrated). The signal connection terminal for an upper arm 327U and the signal connection terminal for a lower arm 327L are arranged in parallel with the DC positive electrode branch terminals 315D, the DC negative electrode branch terminals 319D, and the AC connection terminal 320D.

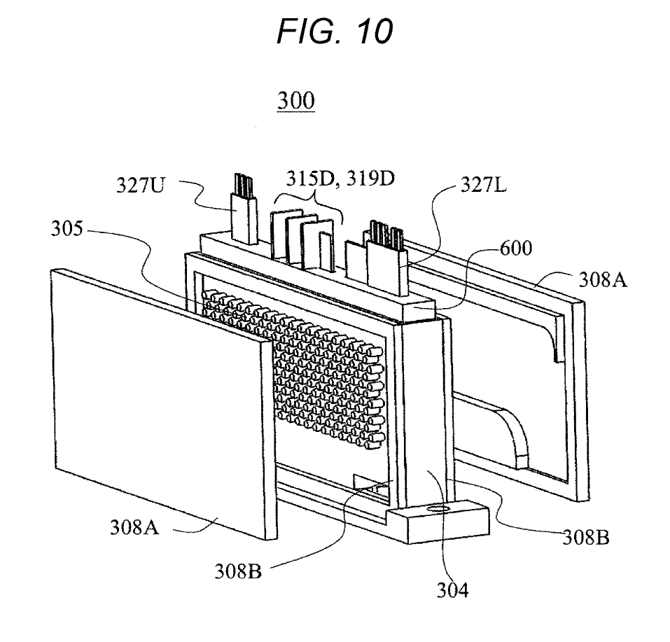

FIG. 9(a), FIG. 9(b), and FIG. 10 are views for describing mounting of the primary sealing body 302 to the cooler 304. As illustrated in FIG. 9(a), the cooler 304 is a flat tubular case including an insertion opening 306 on one surface (surface on upper part in drawing) and a bottom on the other surface. From the insertion opening 306, the primary sealing body 302 is inserted. As illustrated in the exploded perspective view in FIG. 9(b), the cooler 304 includes a frame part 304D and a pair of base parts 307 attached to the frame part 304D.

To the frame part 304D, a channel housing assembling part 311 assembled to the above-described channel housing 251 to form a channel is formed. To the channel housing assembling part 311, an inlet/outlet of a channel 309 is provided. During the assembly with the channel housing 251, a seal member is interposed between the channel housing assembling part 311 and the channel housing and airtightness is secured. Also, a glove for assembly of the seal member may be formed in the channel housing assembling part 311. As the seal member, a silicon-based or fluorine-based O-ring or liquid seal having a superior thermal resistance property is preferably used.

The pair of base parts 307 is attached to the frame part 304D in such a manner as to sandwich the frame part 304D. In a space formed by the frame part 304D and the pair of base parts 307, the primary sealing body 302 is housed. Note that in a peripheral part of the base part 307, a plastically-deformable thin part 307A is formed. Each of the base part 307 functions as a heat radiation wall of the cooler 304 and on an outer peripheral surface thereof, a plurality of fins 305 is formed uniformly.

The cooler 304 includes a member having electric conductivity, such as a composite material of Cu, Cu alloy, Cu—C, Cu—CuO, or the like or a composite material of Al, Al alloy, AlSiC, Al—C, or the like. Also, the cooler 304 may be formed in a case-shape by a joining method, with which a waterproof property becomes high, such as welding or may be formed integrally as a case without a joint by using forging or casting method.

As illustrated in FIG. 9 (a), on each of a surface and a rear surface of the flat primary sealing body 302, a conductor plate exposure part 321 which functions as a heat radiation surface of the conductor plates 315, 318, 319, and 320 is exposed from a first sealing resin 348 used as a sealing material. From a part sealed by the first sealing resin 348, the DC positive electrode branch terminals 315D, the DC negative electrode branch terminals 319D, the signal connection terminal for an upper arm 327U, and the signal connection terminal for a lower arm 327L are stretched upward in the drawing. To these terminal parts, an auxiliary mold body 600 including an insulating material is formed. To the auxiliary mold body 600, a PN wiring insulation part 601 to insulate the DC positive electrode branch terminals 315D and the DC negative electrode branch terminals 319D, which are arranged alternately, from each other and a signal wiring insulation part 602 to insulate the signal connection terminal for an upper arm 327U and the signal connection terminal for a lower arm 327L from an outer part are formed.

As the auxiliary mold body 600, what is formed in advance may be mounted to the primary sealing body 302 or the auxiliary mold body 600 may be molded by performing direct molding to the terminal parts. In a case where the auxiliary mold body 600 formed in advance is mounted to the primary sealing body 302, a plurality of holes for terminals is formed in the auxiliary mold body 600. Then, by inserting the terminals into the holes, the auxiliary mold body 600 is assembled to the primary sealing body 302.

As described above, on each of the surface and the rear surface of the primary sealing body 302, the conductor plate exposure part 321 is exposed. The conductor plate exposure part 321 of the primary sealing body 302 housed in the cooler 304 is thermally in contact with an inner peripheral surface of the base part 307 through an insulating material 333. After the primary sealing body 302 is inserted into the cooler 304, a remaining void in the inner part of the cooler 304 is filled with a second sealing resin 351.

Note that as the sealing resin, for example, a novolac-based, multifunctional, biphenyl-based, or epoxy resin-based resin can be used. By adding ceramics such as SiO2, Al2O3, AlN, or BN, gel, rubber, or the like, a thermal expansion coefficient is made closer to those of the conductor plates 315, 320, 318, and 319. Accordingly, a difference in the thermal expansion coefficient between the members can be reduced and a thermal stress generated along with a rise in temperature in a usage environment is reduced greatly. Thus, it becomes possible to extend a lifetime of the power module. Also, as a molding material of the auxiliary mold body 600, a thermoplastic resin having high heat resistance such as polyphenylsulfide (PPS) or polybutylene terephthalate (PBT) is preferably used.

Heat generated in the IGBTs 328 and 330 and the diodes 156 and 166 is transferred from the conductor plate exposure part 321 to the base part 307 of the cooler 304 through the insulating material 333 and is radiated from the base part 307 to a refrigerant. As illustrated in FIG. 10, a channel cover 308A is fixed to a position facing the base part 307 of the cooler 304 in such a manner as to hold a channel wall 308B and a refrigerant flow channel is formed to a part of the fins 305. The channel wall 308B and the channel cover 308A are fixed to the cooler 304 by adhering or joining. A refrigerant which flows into the refrigerant flow channel between the base part 307 and the channel cover 308A from the inlet/outlet of a channel 309 of the cooler 304 is induced to the fins 305 by the channel cover 308A and the channel wall 308B. Thus, a semiconductor element in the primary sealing body 302 is cooled effectively.

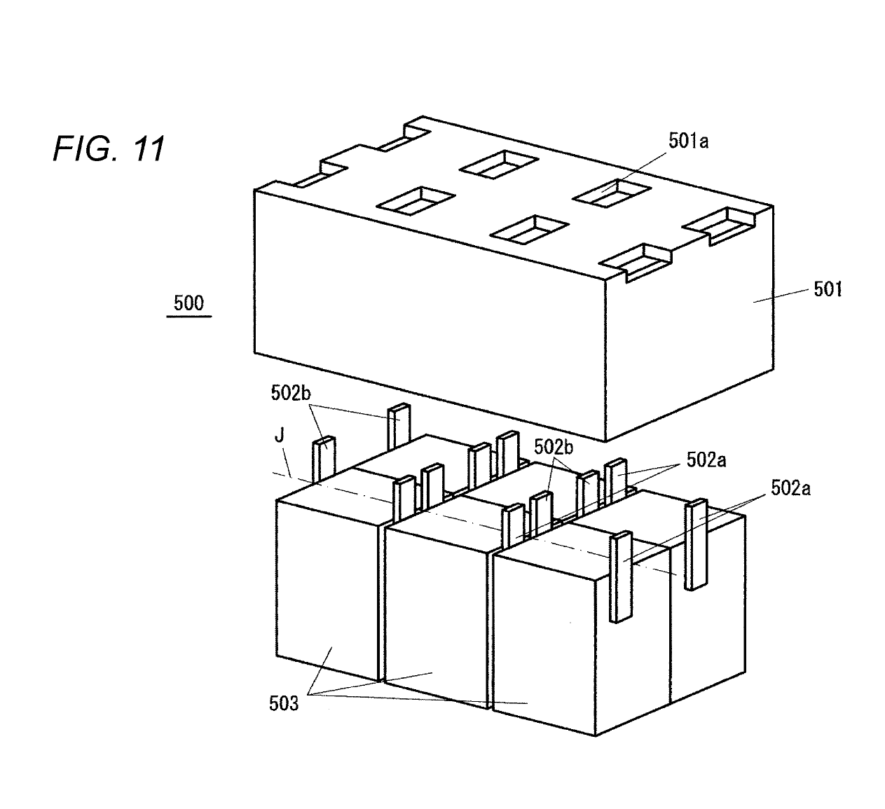

FIG. 11 is an exploded perspective view illustrating an inner structure of the capacitor module 500. The capacitor module 500 is a capacitor case 501 in which a plurality of capacitor cells 503 is embedded. In an example illustrated in FIG. 11, six capacitor cells 503 are provided. To each capacitor cell 503, a positive electrode terminal 502a and a negative electrode terminal 502b are provided in such a manner as to project upward in the drawing. The positive electrode terminal 502a and the negative electrode terminal 502b are shifted to and arranged on both sides of a center shaft J of the capacitor cell 503.

In each capacitor cell 503, the positive electrode terminal 502a and the negative electrode terminal 502b are arranged in two columns in one direction (longitudinal direction of capacitor case 501 in FIG. 11). Positions of the positive electrode terminal 502a and the negative electrode terminal 502b are shifted to right and left from the center shaft J. Thus, when the capacitor cells 503 are lined up in a manner illustrated in FIG. 11, positive electrode terminals 502a and negative electrode terminals 502b of adjoining capacitor cells 503 are arranged in such a manner as to be lined up in a direction orthogonal to the center shaft J. Each capacitor cell 503 is housed in the capacitor case 501 in such a manner that a positive electrode terminal 503a and a negative electrode terminal 503b lined up proximately pierce through an opening 501a formed in an upper wall surface of the capacitor case 501 and project to an outside of the case.

In the present embodiment, the capacitor case 501 is in contact with the power board 700 through a heat transfer member and functions also as a member to transfer heat generated in the power board 700 to the channel housing. Thus, the capacitor case 501 preferably includes a material having high thermal conductivity such as an aluminum alloy-based or copper alloy-based material.

Here, reduction of an inductance of the terminal part in the power module 300 will be described. FIG. 19 is a perspective view illustrating a recovery current path which circulates in an inner part during a switching operation of the both-surface cooling type power module 300. FIG. 20 is a circuit diagram illustrating a recovery current path which circulates in an inner part during the switching operation of the both-surface cooling type power module 300. The power module 300 includes the DC positive electrode branch terminal 315D and the DC negative electrode branch terminal 319D each of which branches into two, the DC positive electrode branch terminal 315D and DC negative electrode branch terminal 319D being arranged alternately. As illustrated in FIG. 19, an induction field 101 generated by a recovery current which pierces through the series circuit of upper and lower arms during the switching operation is canceled and reduced in the DC positive electrode branch terminal 315D and the DC negative electrode branch terminal 319D. As a result, an inductance in a vicinity of the terminal connection part where the greatest number of wiring inductances is distributed can be reduced.

Also, in respect to the power board 700 to which the DC terminal (DC positive electrode branch terminal 315D and DC negative electrode branch terminal 319D) of the power module 300 is connected, an inductance is reduced in the following manner. As illustrated in FIG. 4, the power board 700 connects the DC connector 138 and each capacitor cell 503, and each capacitor cell 503 and the DC terminal (DC positive electrode branch terminal 315D and DC negative electrode branch terminal 319D) of the power module 300. The power board 700 functions as a wiring member to transfer a direct current. In the power board 700 of the present embodiment, a power board P bus bar 703 and a power board N bus bar 704 having large areas are oppositely arranged in parallel as members to wire these. As a result, current density of each part is reduced and a magnetic field generated in vicinity of the power board P bus bar 703 and the power board N bus bar 704 is canceled at the same time. Thus, an inductance of the inverter main circuit as a whole can be reduced. Also, since the power board 700 has a large area, heat radiation performance in respect to joule heat generation can be improved.

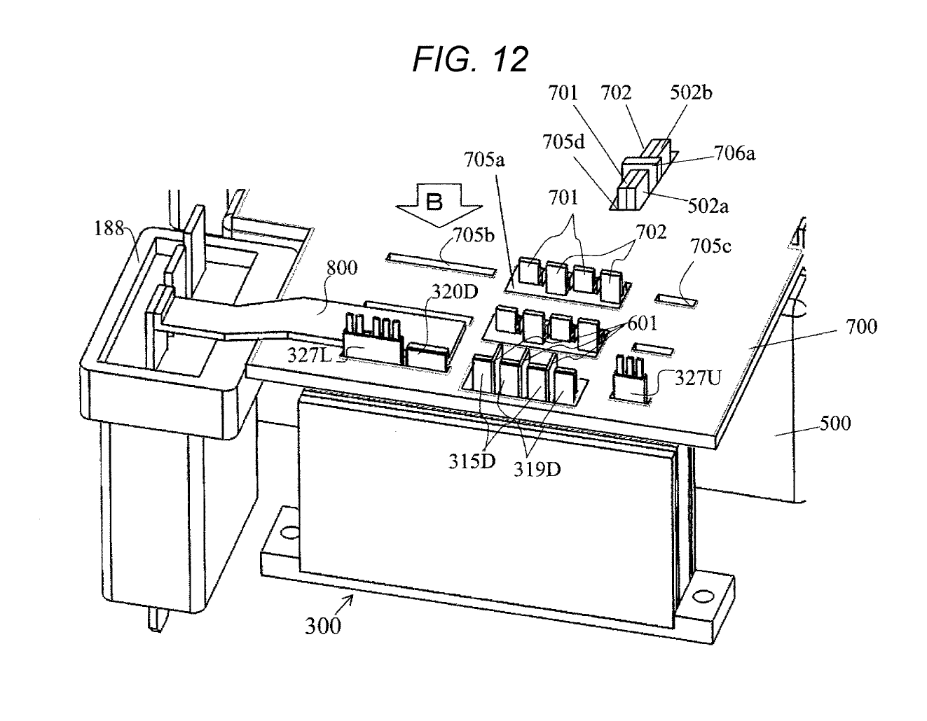

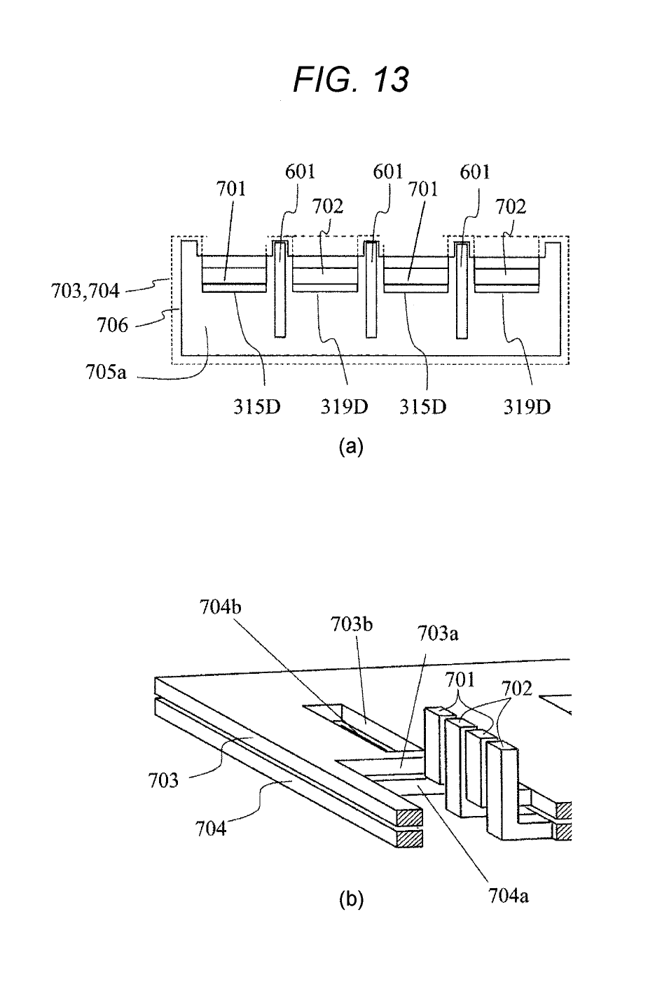

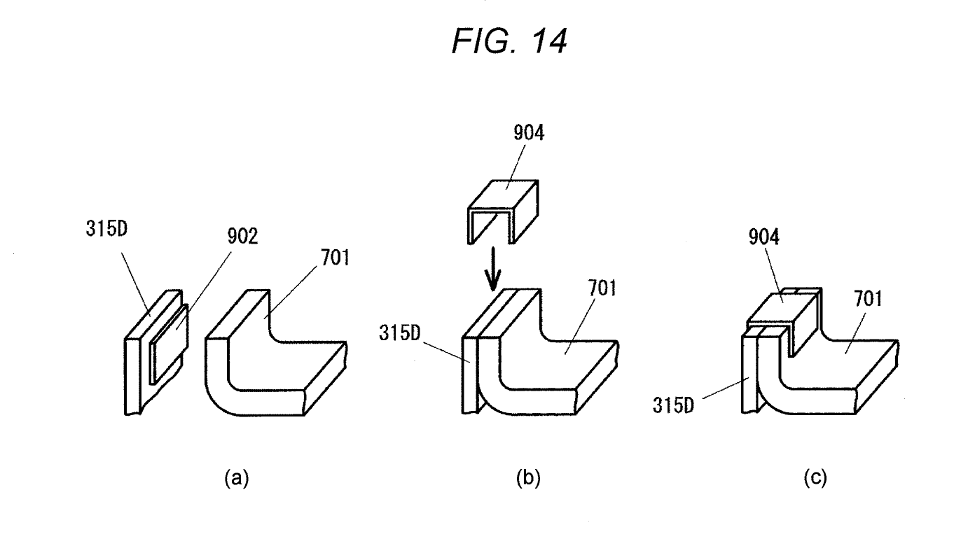

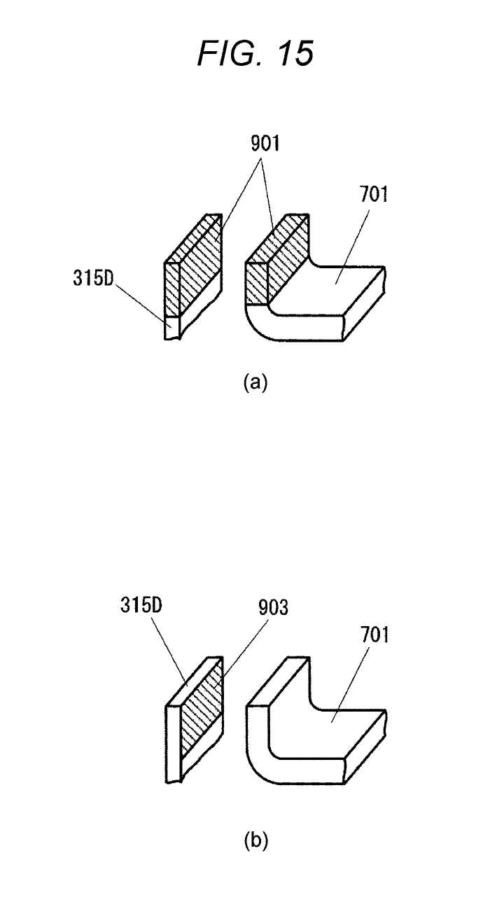

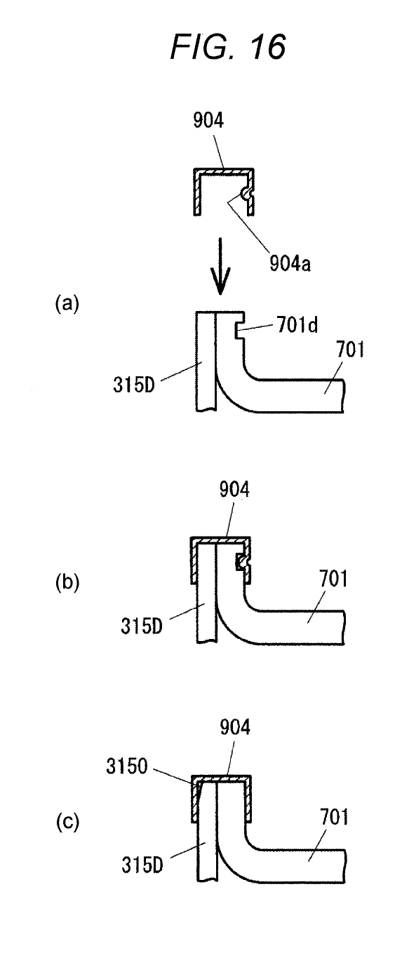

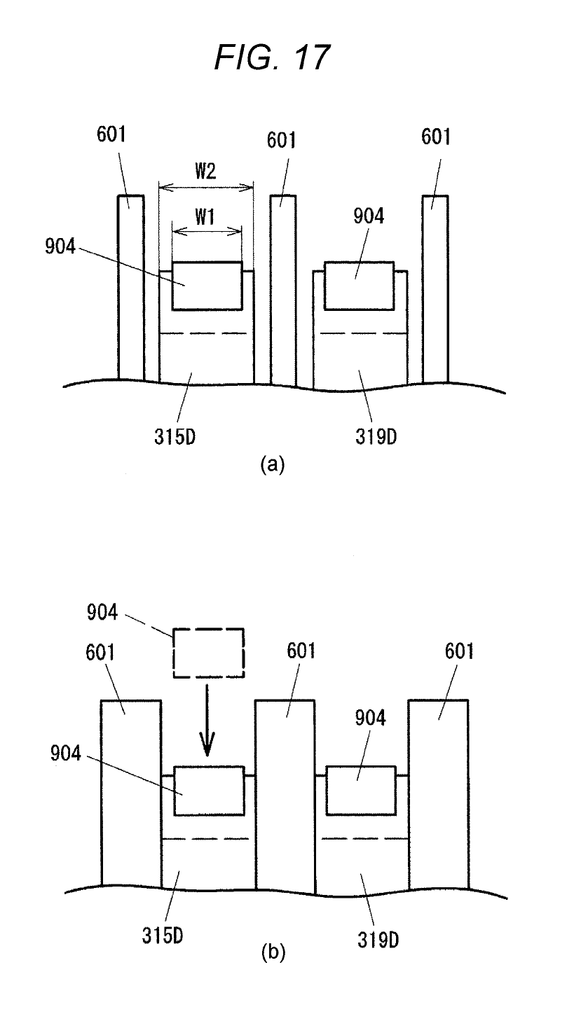

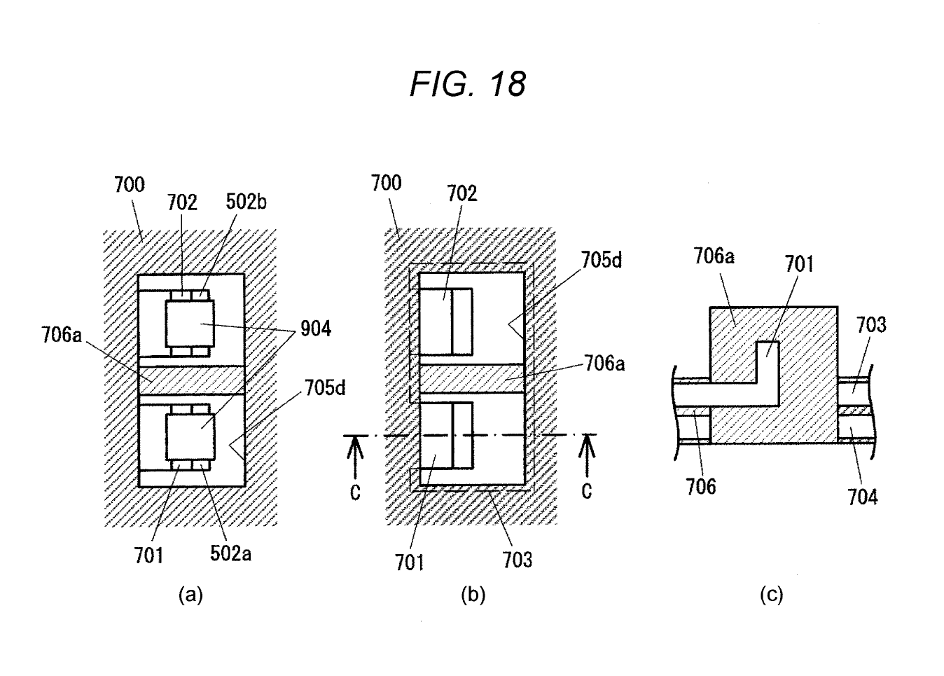

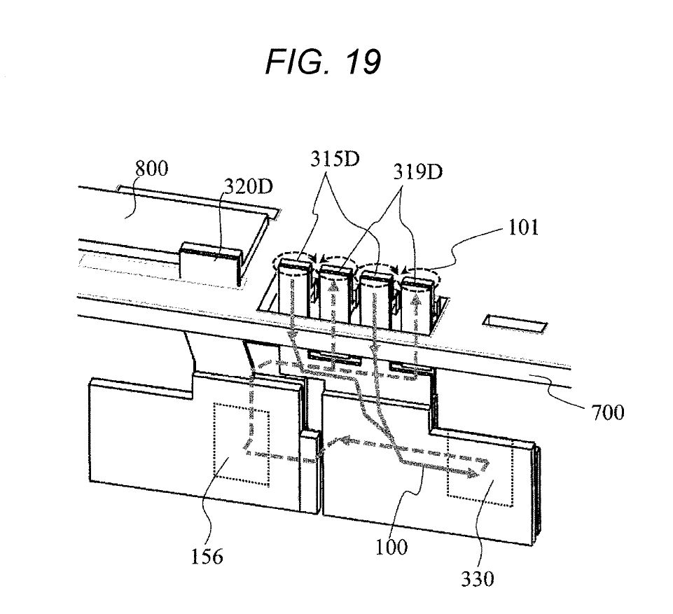

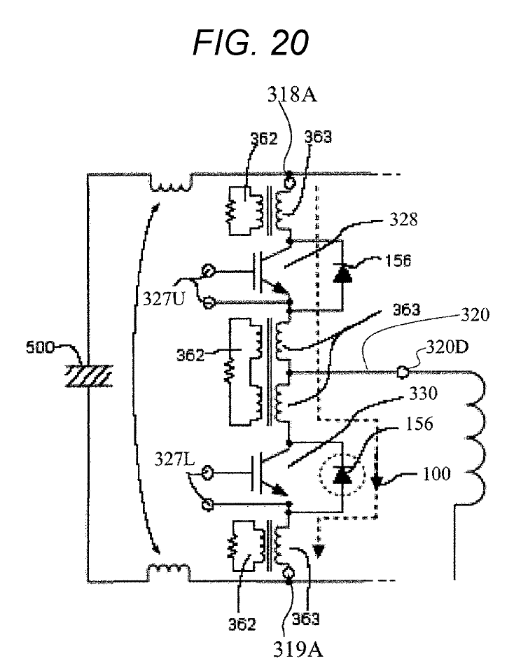

Next, a connection structure of the power module 300, the capacitor module 500, and the power board 700 will be described. FIG. 12 is a view in which a part of the inverter main circuit unit 250 illustrated in FIG. 4 is enlarged and illustrated. FIG. 13 (a) is a plan view of an opening 705a illustrated in FIG. 12. Also, FIG. 13 (b) is a view illustrating a structure of an electrode plate provided to the power board 700.

The power board 700 which is a member to transfer a direct current is formed by performing resin molding of an electrode plate (power board P bus bar 703) which functions as a positive electrode bus bar and an electrode plate (power board N bus bar 704) which functions as a negative electrode bus bar. As illustrated in FIG. 12, in the power board 700, a plurality of openings 705a, 705b, 705c, and 705d is formed. The power module 300 is arranged in such a manner that the DC positive electrode branch terminals 315D and the DC negative electrode branch terminals 319D pierce through the opening 705a, the AC connection terminal 320D and the signal connection terminal for a lower arm 327L pierce through the opening 705b, and the signal connection terminal for an upper arm 327U pierces through the opening 705c.

As illustrated in FIG. 13 (a), to a part of the opening 705a, two P terminals 701 formed on the power board P bus bar 703 and two N terminals 702 formed on the power board N bus bar 704 are arranged. The P terminals 701 and the N terminals 702 are arranged alternately in a longitudinal direction of the opening. As described above, the power board P bus bar 703 and the power board N bus bar 704 are molded by a resin member 706 having an insulation part property except the P terminals 701, the N terminals 702, and the above-described power board DC terminal 707. A dashed line illustrated in FIG. 13(a) corresponds to the opening 705a of the power board 700 and indicates an opening formed in each of the power board P bus bar 703 and the power board N bus bar 704.

FIG. 13 (b) is a view illustrating shapes of the power board P bus bar 703 and the power board N bus bar 704 in the part of the openings 705a and 705b of the power board 700. In FIG. 13 (b), the resin member 706 is not illustrated in order to make it easier to understand a shape of the bus bar. The resin member 706 which functions as an insulating member is provided in such a manner as to cover surfaces and rear surfaces of the bus bars 703 and 704. The resin member 706 is interposed in a gap between the bus bars 703 and 704 illustrated in FIG. 13(b). Note that openings 703a and 704a and openings 703b and 704b are formed in the bus bars 703 and 704 in such a manner as to correspond to the openings 705a and 705b of the power board 700. Then, the P terminals 701 are formed on a part of the opening 703a of the power board P bus bar 703, and the N terminals 702 are formed on a part of the opening 704a of the power board N bus bar 704.

When the power module 300 is arranged in a manner illustrated in FIG. 12, in the part of the opening 705a, the P terminals 701 and the DC positive electrode branch terminals 315D are connected to each other and the N terminals 702 and the DC negative electrode branch terminals 319D are connected to each other. As described above, the PN wiring insulation part 601 is provided between each of the DC positive electrode branch terminals 315D and the DC negative electrode branch terminals 319D. The PN wiring insulation part 601 functions as a barrier to insulate a positive electrode (connection part of P terminal 701 and DC positive electrode branch terminal 315D) and a negative (connection part of N terminal 702 and DC negative electrode branch terminal 319D) from each other.

FIG. 14(a) to FIG. 14(c) are views for describing a procedure of connecting each of the P terminals 701 and each of the DC positive electrode branch terminals 315D. In a step illustrated in FIG. 14(a), when the power module 300 is arranged in such a manner that the DC positive electrode branch terminal 315D pierces through the opening 705a, a metal joining member (such as solder sheet) 902 is sandwiched between the P terminal 701 and the DC positive electrode branch terminal 315D. Then, as illustrated in FIG. 14(b), a substantially U-shaped flexion member 904 is elastically deformed and is mounted in such a manner as to sandwich (that is, to grasp) a leading end of each of the P terminal 701 and the DC positive electrode branch terminal 315D. FIG. 14(c) is a view illustrating a state in which the flexion member 904 is mounted. Then, by heating the connection part in the state illustrated in FIG. 14 (c) by using an iron or the like, the metal joining member 902 is melted and solidified again. Thus, the P terminal 701 and the DC positive electrode branch terminal 315D are joined.

In a case where such a sheet-like metal joining member 902 is used, a metal joining member can be arranged during the assembling. Thus, it is possible to deal flexibly with a case of changing a kind, a size, or the like of the metal joining member.

Note that the flexion member 904 may be mounted after a metal joining member 903 is melted and solidified again. However, when the metal joining member 903 is melted and solidified again after the connection part is sandwiched by the flexion member 904, there is an advantage that the melted metal joining member 903 reaches a part of the flexion member 904 and it becomes difficult to detach the flexion member 904.

In the example illustrated in FIG. 14 (a) to FIG. 14 (c), the sheet-like metal joining member 902 is arranged between the P terminal 701 and the DC positive electrode branch terminal 315D. However, a configuration illustrated in FIG. 15(a) or FIG. 15 (b) is also possible. In an example illustrated in FIG. 15 (a), metal plating 901 having a low melting point such as Sn is applied to a joint part of the P terminal 701 and the DC positive electrode branch terminal 315D and the connection part is heated and the plating is melted after the flexion member 904 is mounted, whereby connection is performed. In an example illustrated in FIG. 15 (b), the paste-like metal joining member 903 is applied on at least one of facing surfaces of the P terminal 701 and the DC positive electrode branch terminal 315D.

In a case where a plating layer is formed as a metal joining member, plating is applied to the connection part in advance, and thus, assemblability can be improved. Also, in a case of the paste-like metal joining member 903, a position is not shifted during assembling, and thus, the assembling becomes easier.

Also, a shape of the flexion member 904 may be, for example, a shape illustrated in FIG. 16(a). In an example illustrated in FIG. 16(a), a recess part 701d is formed in the P terminal 701 and a protruded part 904a to be engaged with the recess part 701d is formed in an inner periphery side of the flexion member 904. When the flexion member 904 is mounted to a terminal part in a manner illustrated in FIG. 16(b), by making sure that the protruded part 904a is engaged with the recess part 701d, it can be easily checked whether the flexion member 904 is mounted correctly. Moreover, it becomes difficult to detach the flexion member 904 from the terminal part. Note that a recess part may be formed in the DC positive electrode branch terminal 315D.

Furthermore, in FIG. 16(c), by forming a tapered surface 3150 on an outer side of the leading end of the DC positive electrode branch terminal 315D, mounting operation of the flexion member 904 becomes easier. Of course, a tapered surface may be formed on a side of the P terminal 701.

Note that connection of the N terminal 702 with the DC negative electrode branch terminal 319D, and connection of the P terminal 701 with the DC positive electrode branch terminal 315D are performed in a similar manner. Also, the positive electrode terminal 502a and the negative electrode terminal 502b of each capacitor cell 503 provided to the capacitor module 500 are respectively connected to the P terminal 701 and the N terminal 702 in a similar manner. Note that in FIG. 12 and FIG. 13(a), the flexion member 904 is not illustrated in order to make it easier to understand a connection structure of the terminal part.

In the present embodiment, as described above, the DC positive electrode branch terminals 315D and the DC negative electrode branch terminals 319D of the power module 300 are proximately and alternately arranged to reduce an inductance. Then, the PN wiring insulation part 601 which is a member for insulation is provided between a proximate positive electrode terminal and negative electrode terminal. Thus, when fusion joining, such as TIG welding, to melt a terminal material and to join the terminals 315D and 319D with the terminals 701 and 702 is used, an arc is generated therearound and a radiant heat becomes high. Thus, there is a trouble that the PN wiring insulation part 601 provided proximately to the terminal is melted.

Thus, in the present embodiment, instead of the fusion joining, terminals are joined by a “brazing and soldering (such as brazing or soldering)” using a metal joining member having a melting point lower than that of a material (such as copper material) used for the terminals 315D and 319D and the terminals 701 and 702. In the brazing and soldering, only the metal joining member is melted and solidified again, and thus, metal joining of the terminals is performed. Thus, the connection part is not just adhered, a layer of a metallic bond being formed thereon. Since the layer of a metallic bond is formed, electric resistance in the connection part becomes small and low heat is generated even when a large current flows in the connection part. Moreover, it is possible, for example, to prevent water from entering the connection part or to prevent the connection part from being oxidized. Thus, deterioration in a long period of use can be prevented.

However, in a case of such brazing and soldering, joint strength is slightly weak compared to fusion joining to melt and join a terminal material. Specifically, in a case where application to an in-vehicle power conversion apparatus such as what is described in the present embodiment is performed, vibration during driving of a vehicle is applied to a joint part. Thus, in the present embodiment, the flexion member 904 to support joint strength of a joint part is mounted to a leading end of a connection part. As illustrated in FIG. 14(a) to FIG. 14(c), the flexion member 904 is mounted over a leading end of each of the terminals 315D and 701 and holds the terminals 315D and 701. As a material of the flexion member 904, an optimal material for realizing a holding function is selected. For example, a spring material can be used. By using the flexion member 904, it is possible to control falling away of a terminal connection part caused by an external force due to vibration, thermal deformation, or the like during a use.

On the other hand, as illustrated in FIG. 12, the AC connection terminal 320D provided to the power module 300 pierces through the opening 705b of the power board 700 and is connected to the AC bus bar 800 in an upper side of the power board 700. For joining of the AC connection terminal 320D and the AC bus bar 800, conventional welding and joining may be used or brazing and soldering using a metal joining member having a low melting point may be used similarly to the case of the terminals 315D and 319D. In a case where the brazing and soldering is employed, the flexion member 904 is mounted to a leading end part of the terminal.

As described, since each of the DC positive electrode branch terminals 315D and each of the DC negative electrode branch terminals 319D are provided proximately, the PN wiring insulation part 601 is provided for insulation between the terminals. In this case, a creepage distance between the DC positive electrode branch terminal 315D and the DC negative electrode branch terminal 319D is set long, and thus, a sufficient creepage insulation property can be acquired. Thus, in the present embodiment, as illustrated in FIG. 17(a), a leading end of the PN wiring insulation part 601 projects upward compared to the terminal part to which the flexion member 904 is mounted. Also, a creepage distance on a side of the terminal is made long by widening a width of the PN wiring insulation part 601 as illustrated in FIG. 13 (b). With configurations illustrated in FIG. 13 (b), FIG. 17 (a), and FIG. 17 (b), a spatial distance between the terminals can also be made long.

Note that as illustrated in FIG. 14 (a) to FIG. 14 (c), the flexion member 904 is mounted over the leading end of each of the terminals 315D and 701. Thus, as described above, even when the leading end of the PN wiring insulation part 601 projects upward compared to the leading end of each of the terminals 315D and 701, it is possible to mount the flexion member 904 easily and to make the flexion member 904 grip the connection part securely.

In the example illustrated in FIG. 17 (a), gaps are formed respectively between the DC positive electrode branch terminal 315D and the PN wiring insulation part 601 and between the DC negative electrode branch terminal 319D and the PN wiring insulation part 601. However, as illustrated in FIG. 17 (b), the DC positive electrode branch terminal 315D and the DC negative electrode branch terminal 319D may be in contact with the PN wiring insulation part 601. In a case of a configuration in FIG. 17(a) in which a gap is generated, even when a width W1 of the flexion member 904 and a width W2 of the terminal are identical, the width does not become an obstacle in mounting operation of the flexion member 904. On the other hand, in a case of FIG. 17 (b), when setting is performed in a manner of W1=W2, mounting becomes difficult. Thus, setting in a manner of W1<W2 is preferred.

(Connection of Terminals 502a and 502b)

Note that as illustrated in FIG. 12, the positive electrode terminal 502a of the capacitor cell 503 is connected to the P terminal 701 formed in the part of the opening 705d. The negative electrode terminal 502b is connected to the N terminal 702. Joining of the terminals 502a and 502b with the terminals 701 and 702 is performed similarly to the case of the DC terminal of the power module 300. That is, brazing and soldering to melt a metal joining member and to join the terminals is used. Also, the flexion member 904 is mounted over a leading end part of the connection terminal.

FIG. 18(a) to FIG. 18(c) are views in which the part of the opening 705d is enlarged and illustrated. FIG. 18(a) is a plan view, FIG. 18(b) is a plan view only illustrating the power board 700, and FIG. 18(c) is a C-C sectional view. A hatched part indicates the resin member 706. The resin member 706 forms an insulating barrier 706a in a region of the opening 705d. The insulating barrier 706a includes a function similar to that of the above-described PN wiring insulation part 601 and is provided to secure a spatial distance and a creepage distance between a terminal on the positive electrode side (positive electrode terminal 502a and P terminal 701) and a terminal on the negative electrode side (negative electrode terminal 502b and N terminal 702).

As described above, in the present embodiment, the following function effect can be provided.

(1) In the inverter apparatus 140 which is an electric circuit apparatus, the DC positive electrode branch terminal 315D and the P terminal 701 are connected to each other and the DC negative electrode branch terminal 319D and the N terminal 702 are connected to each other via the metal joining member 902 having a melting point lower than those of the terminals. Thus, compared to a case of using fusion joining, a thermal influence on the resin member 706 in vicinity can be reduced. Also, the DC positive electrode branch terminal 315D and the P terminal 701 are held by the flexion member 904 and the DC negative electrode branch terminal 319D and the N terminal 702 are held by the flexion member 904. Thus, connection durability can be improved.

Also, as illustrated in FIG. 14(a) to FIG. 14(c), in a state in which the metal joining member 902 having a melting point lower than those of the branch terminals 315D and 319D and the terminals 701 and 702 is arranged, a leading end part of each of the branch terminals 315D and 319D and a leading end part of each of the terminals 701 and 702 are held integrally by the flexion member 904. Then, the metal joining member 902 is melted and solidified again. Accordingly, the connection part is fixed tightly by the flexion member 904 and falling away of the metal joint part can be prevented.

(2) As an electric circuit component, there are the power module 300, the capacitor cell 503 which configures the capacitor module 500, and the like. For example, in a case of the power module 300, as illustrated in FIG. 13(a), the DC positive electrode branch terminal 315D and the DC negative electrode branch terminal 319D of the power module 300 are lined up and the flexion member 904 is arranged over the leading end of each of the DC positive electrode branch terminal 315D and the P terminal 701. Also, the flexion member 904 is arranged over the leading end of each of the DC negative electrode branch terminal 319D and the N terminal 702. Also, in a case of the capacitor cell 503, as illustrated in FIG. 11, a positive electrode terminal 502a of a capacitor cell 503 and a negative electrode terminal 502b of an adjoining capacitor cell 503 are lined up proximately. In either case, the PN wiring insulation part 601 and the insulating barrier 706a as insulating barriers are provided in such a manner as to project compared to the mounted flexion member 904. Thus, a creepage insulation property can be improved.

Also, as illustrated in FIG. 18 (a) to FIG. 18 (c), a flexion member 904 is arranged over the leading end of each of the positive electrode terminal 502a and the P terminal 701 and a flexion member 904 is arranged over the leading end of each of the negative electrode terminal 502b and the N terminal 702. Thus, even when a leading end part of each of the PN wiring insulation part 601 and the insulating barrier 706a, which are insulating members, is projected compared to the flexion member 904, the connection part can be securely sandwiched.

(3) Also, as illustrated in FIG. 17(b), the PN wiring insulation part 601 which is an insulating barrier is configured in such a manner as to be in contact with a side surface on a width side of each of the DC positive electrode branch terminal 315D and the DC negative electrode branch terminal 319D. A width W1 in the width direction of the flexion member 904 is set narrower than a width W2 of each of the terminals 315D and 319D. As a result, the flexion member 904 can sandwich the connection part without touching the PN wiring insulation part 601. Thus, damage of the PN wiring insulation part 601 can be prevented and productivity can be improved.

(4) As illustrated in FIG. 16(c), by forming the tapered surface 3150 on the leading end of the DC positive electrode branch terminal 315D, attachment of the flexion member 904 becomes easier in sandwiching the connection part with the flexion member 904, and thus, productivity is improved. The tapered surface can be formed on the P terminal 701 or on both of the DC positive electrode branch terminal 315D and the P terminal 701.

(5) Also, the recess part 701d is formed in at least one of the DC terminal (315D or 319D) and the connection terminal part (701 or 702) which are connected to each other. In an example illustrated in FIG. 16 (a), the recess part 701d is formed on a surface, which faces the flexion member 904, of the P terminal 701. On a surface, which faces the recess part 701d, of the flexion member 904, the protruded part 904a to be engaged with the recess part 701d is formed. Thus, it is possible to perform secure mounting easily and it becomes difficult to detach the flexion member 904 from the connection part, and thus, reliability for a long period of use can be improved. Note that a recess part may be formed in the DC positive electrode branch terminal 315D or a recess part may be formed in the both. In such a case, the protruded part 904a is formed on each surface, which faces the recess part, of the flexion member 904. Either case includes similar effects.

Note that the above description is just an example. Interpretation of the invention is not limited to a correspondence relationship between the described items in the embodiment and the described items in the claims. For example, in the above-described embodiment, the description has been made with the inverter apparatus 140 as an example of an electric circuit apparatus. However, the present invention can be applied to various electric circuit apparatuses as long as connection terminals, which are resin members arranged proximately, are connected to each other by metal joining.

### REFERENCE SIGNS LIST

143 power conversion apparatus
300 power module
315D DC positive electrode branch terminal
319D DC negative electrode branch terminal
500 capacitor module
502a positive electrode terminal
502b negative electrode terminal
503 capacitor cell
601 PN wiring insulation part
700 power board
701 P terminal
701d recess part
702 N terminal
703 power board P bus bar
704 power board N bus bar
706 resin member
706a insulating barrier
800 AC bus bar
901 metal plating
902, 903 metal joining member
904 flexion member
904a protruded part
3150 tapered surface

1. An electric circuit apparatus comprising:
an electric circuit component including a DC terminal;
a power board configured to transfer a direct current, the power board including a positive electrode plate and a negative electrode plate sealed by a resin sealing material, which has an insulation property, in such a manner that a connection terminal part is exposed; and
a flexion member which is connected via a metal joining member having a melting point lower than those of the DC terminal and the connection terminal part, and which holds the DC terminal and the connection terminal part.

2. The electric circuit apparatus according to claim 1, wherein
the electric circuit component is a power semiconductor module configured to convert a direct current into an alternating current,
the DC terminal includes a positive electrode-side terminal and a negative electrode-side terminal which is lined up with the positive electrode-side terminal,
the connection terminal part includes a first connection terminal part formed on the positive electrode plate and a second connection terminal part formed on the negative electrode plate,
the flexion member includes a first flexion member arranged over a leading end of each of the positive electrode terminal and the first connection terminal part connected to each other and a second flexion member arranged over a leading end of each of the negative electrode terminal and the second connection terminal part connected to each other, and
an insulating barrier provided between the positive electrode terminal and the negative electrode terminal in such a manner as to project compared to the first and second flexion members arranged at the leading ends thereof is further included.

3. The electric circuit apparatus according to claim 2, wherein
the insulating barrier is provided in such a manner as to be in contact with a side surface in a width direction of each of the positive electrode terminal and the negative electrode terminal,
a size in the width direction of the first flexion member is set smaller than a width of the positive electrode-side terminal, and
a size in the width direction of the second flexion member is set smaller than a width of the negative electrode-side terminal.

4. The electric circuit apparatus according to claim 1, wherein
the electric circuit component is first and second capacitors configured to smooth a direct voltage,
a positive electrode terminal of the first capacitor is lined up with a negative electrode terminal of the second capacitor,
the connection terminal part includes a first connection terminal part formed on the positive electrode plate and a second connection terminal part formed on the negative electrode plate,
the flexion member includes a first flexion member arranged over a leading end of each of the positive electrode terminal and the first connection terminal part connected to each other and a second flexion member arranged over a leading end of each of the negative electrode terminal and the second connection terminal part connected to each other, and
an insulating barrier provided between the positive electrode terminal and the negative electrode terminal in such a manner as to project compared to the first and second flexion members arranged at the leading ends thereof is further included.

5. The electric circuit apparatus according to claim 1, wherein a tapered surface is formed on a leading end of at least one of the DC terminal and the connection terminal part connected to each other.

6. The electric circuit apparatus according to claim 1, wherein
a recess part is formed on a surface, which faces the flexion member, of at least one of the DC terminal and the connection terminal part connected to each other, and
a protruded part to be engaged with the recess part is formed on a surface, which faces the recess part, of the flexion member.

7. A method for producing an electric circuit apparatus including an electric circuit component which includes a DC terminal, and a power board which is configured to transfer a direct current and which includes a positive electrode plate and a negative electrode plate sealed by a resin sealing material, which has an insulation property, in such a manner that a connection terminal part is exposed, the method comprising:
a first step in which a leading end part of the connection terminal part and a leading end part of the DC terminal are held integrally by a flexion member in a state in which a metal joining member having a melting point lower than those of the connection terminal part and the DC terminal is arranged therebetween; and
a second step in which the connection part and the terminal are connected to each other by melting the metal joining member and solidifying the metal joining member again.

8. The method for producing an electric circuit apparatus according to claim 7, wherein a plating layer including the metal joining member is formed on at least one of facing surfaces of the connection terminal part and the DC terminal.

9. The method for producing an electric circuit apparatus according to claim 7, wherein the metal joining member is a sheet-like metal joining member.

10. The method for producing an electric circuit apparatus according to claim 7, wherein the metal joining member is a paste-like metal joining member.
